(19) United States
(12) Patent Application Publication
(10) Pub. No.: US 2021/0121952 A1
(43) Pub. Date: Apr. 29, 2021

(54) COVER FOR DEVICES

(71) Applicant: HEWLETT-PACKARD DEVELOPMENT COMPANY, L.P., SPRING, TX (US)

(72) Inventors: CHI HAO CHANG, TAIPEI CITY (TW); KUAN-TING WU, TAIPEI CITY (TW); KUO CHIH HUANG, TAIPEI CITY (TW); CHUNG HUA KU, TAIPEI CITY (TW)

(21) Appl. No.: 16/605,766

(22) PCT Filed: Jun. 6, 2017
(86) PCT No.: PCT/US2017/036176

§ 371 Date: Oct. 16, 2019

(51) Int. Cl. B22F 1/02; B22F 1/00; C09D 5/03; C23C 14/22; C09D 1/00; B05D 5/06; B05D 7/00; H01Q 1/40

(52) U.S. Cl. CPC B22F 1/025; B22F 1/0018; B22F 1/0055; C09D 5/032; B82Y 30/00; C09D 1/00; B05D 5/061; B05D 7/52; H01Q 1/40; C23C 14/223

(57) ABSTRACT

In an example, a device cover may comprise a substrate and a metal luster layer having a lustrous paint formulation applied to an outer surface of the substrate. The lustrous paint formulation may comprise base particles with surfaces partially coated with metal nanoparticles. The metal nanoparticles may be disposed in a non-continuous manner on the base particles.

### BACKGROUND

Electronic devices, such as computing devices are no longer restricted for office use but are widely used for personal purposes as well. With the increase in popularity, and in addition to configuration and functions performed by a computing device, there has been an emphasis on enhancing aesthetics of the electronic devices. For example, to enhance the aesthetics, a lustrous finish, such as a metal finish, may be provided on an exterior surface of an electronic device.

### BRIEF DESCRIPTION OF THE DRAWINGS

FIG. 1 is a schematic view of an example device having an example cover.

FIG. 2 is a schematic view of an example cover.

FIG. 3 is a schematic diagram illustrating preparation of an example lustrous paint formulation for an example cover.

FIGS. 4A-4E are schematic sectional views of an example cover.

FIG. 5 is a diagram of a method for preparing an example lustrous paint formulation.

FIG. 6 is a diagram of a method for fabricating an example cover.

### DETAILED DESCRIPTION

With advances in technology, electronic devices have become ubiquitous. In addition to being assessed based on configuration, electronic devices are often evaluated based on aesthetics. The aesthetics may include, for example, a lustrous finish provided on an exterior surface of the electronic device. To provide a lustrous finish, the exterior surface may be coated with a paint layer, which may include, for example, metal particles to provide luster to the exterior surface. In some cases, such metal particles may interfere with the working of an antenna of the electronic device. For example, the metal particles may allow flow of electric current, which in turn may interfere with electromagnetic waves received and transmitted by the antenna. This in turn may adversely affect the performance of the antenna, and hence, the electronic device.

A lustrous paint formulation and approaches to provide such a formulation and other articles thereof, are described. The example lustrous paint formulation while providing for luster, does not interfere with communication components, such as an antenna. The lustrous paint formulation, hereinafter referred to as paint formulation, may be composed of particles partially coated with metal nanoparticles. In an example, the metal nanoparticles may include a metal or an alloy. Prior to being coated with the metal nanoparticles, the particles may be referred to as base particles, may be composed of organic particles, inorganic particles, or composite particles. To coat the base particles with the metal nanoparticles, a deposition process, such as physical vapor deposition (PVD), may be used. While performing the PVD, the base particles may be coated with the metal nanoparticles such that the metal nanoparticles do not cover an entire surface of the base particle, i.e., the base particles may be partially coated with the metal nanoparticles. In an example, the resulting formulation includes particles having non-continuous metal nanoparticle coating.

Using the paint formulation, a lustrous paint may be prepared for coating or applying onto a device cover. To provide the luster, a layer of the lustrous paint may be deposited on the device cover. As the particles are partially coated with the metal nanoparticle, a discontinuous metal luster layer is formed, resulting in the metal luster layer to be no longer conductive. Accordingly, while the metal nanoparticles provide for luster, owing to partial coating of the nanoparticles on the particles, the flow of electric current through the metal luster layer is avoided. Thus, transmission and receipt of the electromagnetic waves may not be affected by the metal luster layer, thereby not affecting antenna performance.

Further, the lustrous paint formulation may be a lustrous metallic flake paint. The lustrous metallic flake paint may include lustrous flakes comprising a flake substrate coated with a flake coating layer and suspended in a paint coating. The lustrous flakes may be non-continuous throughout the paint coating (i.e., may be suspended non-continuously) and thus may provide a lustrous finish and/or appearance, yet may not interfere with communications components, such as an antenna. Additionally, the lustrous paint formulation may be a lustrous powder coat. The lustrous powder coat may contain powder beads, also referred to as base particles, which may be non-continuously coated with metal or metallic nanoparticles, providing a lustrous quality to the beads. The lustrous powder coat may be cured, spreading the powder beads into a continuous coat over a device cover, yet the non-continuous nature of the metal nanoparticles may provide an electrically non-conductive quality to the lustrous powder coat, thereby avoiding interfering with communications components, such as an antenna.

The following detailed description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

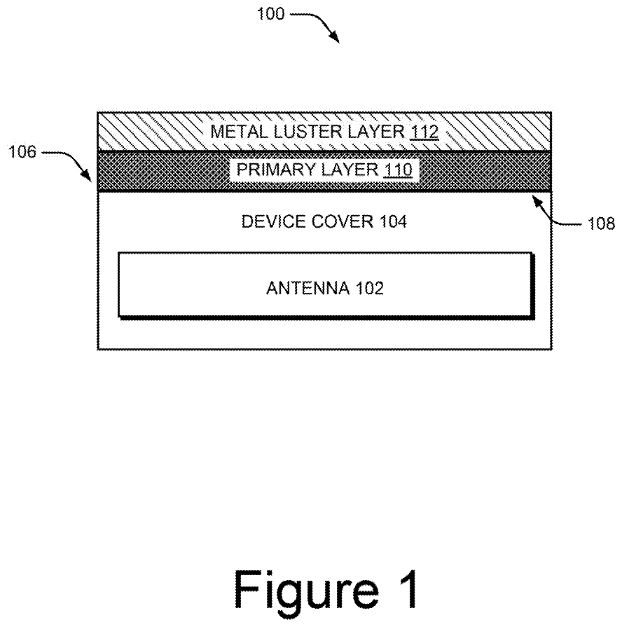

FIG. 1 illustrates a schematic diagram of an electronic device 100, according to an example implementation of the present subject matter. The device 100 may be a personal computer (PC), a laptop, a tablet PC, a mobile phone, a smart camera, a set top box (STB) or any other electronic device having an antenna. Further, the device 100 may include, among other things, an antenna 102 to facilitate communication and a device cover 104, hereinafter referred to as cover 104, housing the antenna 102. The antenna 102 may be an electrical component of the device 100 that provides for communication by sending and receiving electromagnetic signals. The antenna 102 may be operated to communicate with other devices.

Further, the cover 104 of the device 100 may be a part of a body of the device 100. In another example, the cover 104 may be separately provided on the device 100. The cover 104 may include a lustrous external surface to enhance the aesthetics of the device 100. In an example, the cover 104 may be provided with certain structural features for the aforementioned purpose. For example, the cover 104 may be provided with one or multiple layers thereon to provide a desired aesthetic quality.

The layers may be provided on an outer surface 106 of the cover 104, or a substrate thereof, while an inner surface 108 may face internal components, such as the antenna 102. The inner surface may be opposite to the outer surface, in some implementations. The cover 104 may include a primary layer 110 applied over the outer surface 106 and a metal luster layer 112 applied over the primary layer 110. The primary layer 110 may be act as a bridge layer between the cover 104 and the metal luster layer 112 to provide better adhesion and to enhance aesthetics. The metal luster layer 112 may be provided as an exterior layer for enhancing aesthetics of the cover 104 and the device 100. The metal luster layer 112 is composed of partially coated particles or flakes. Such particles may include base particles partially coated with metal nanoparticles to provide luster to the cover 104. Similarly, such flakes may include a flake substrate coated with a metallic layer and non-continuously suspended in a paint coating. As the particles are not completely coated with the metal (metal nanoparticles) and/or the flakes are not continuously suspended in the paint coating, the metal luster layer 112 composed of such particles and flakes may be incapable of electrically conducting, thereby not interfering with the working of the antenna 102. Thus, the metal luster layer 112 adds to the aesthetics and at the same time ensures the performance of the antenna 102.

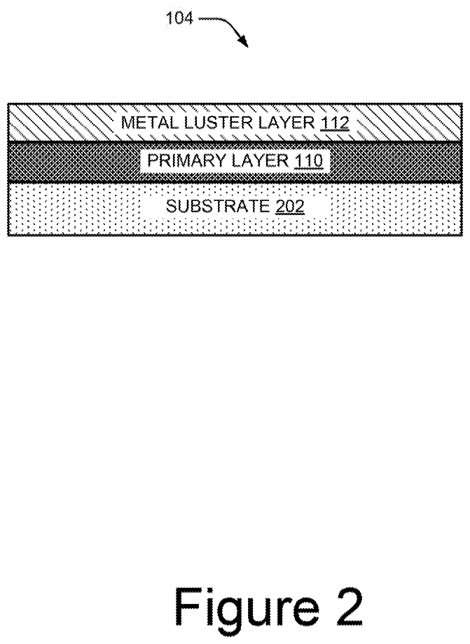

FIG. 2 illustrates a schematic diagram illustrating the cover 104, in accordance with an example implementation of the present subject matter. As mentioned previously, the cover 104, in addition to other things, provides for enhancing the aesthetics of the device 100. The cover 104 may be a detachable or non-detachable part of the body of the device 100. In an example, the cover 104 may cover an antenna slot of the device 100. In another example, the cover 104 may cover the whole of device 100.

In one example, the cover 104 includes a substrate 202, a primary layer 110, and a metal luster layer 112. The substrate 202 may be a skeleton structure of the cover 104 over which the coatings may be applied. During operation of the device 100, the substrate 202 may be in proximity to the antenna 102. A surface of the substrate 202 that faces the antenna 102 may correspond to the inner surface 108. Further, another surface of the substrate 202 that faces away from the antenna 102, i.e., the surface that is exposed to surroundings and comes in contact with the user, may correspond to the outer surface 106. The substrate 202 may comprise a metal, a metal alloy, a polymer, a carbon fiber, a ceramic, and/or a composite material, to provide sturdiness and durability to the cover 104. In an example, the substrate 202 may include one of aluminum, magnesium, zinc, titanium, lithium, niobium, carbon steel, stainless, copper, iron, silicon carbide, and alloys thereof.

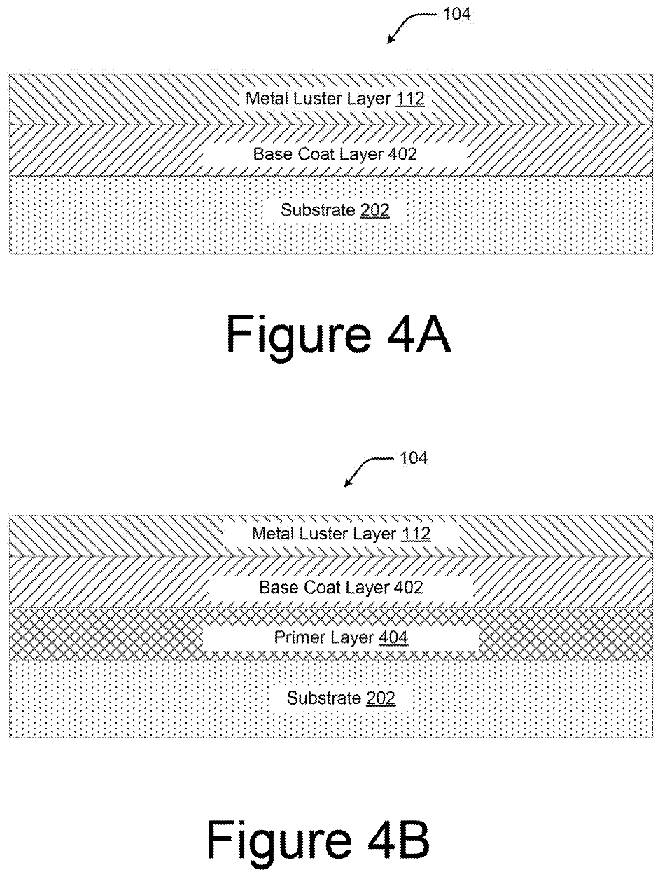

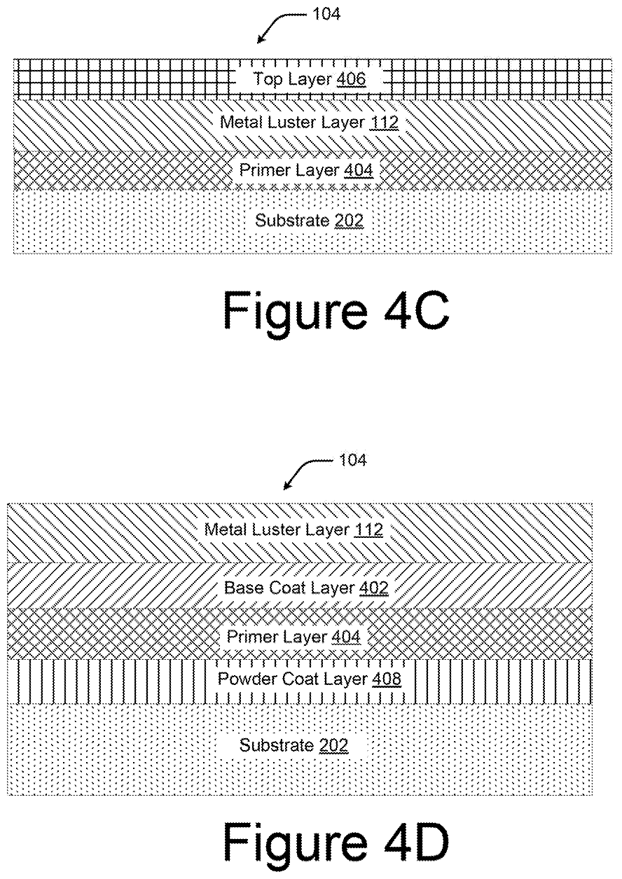

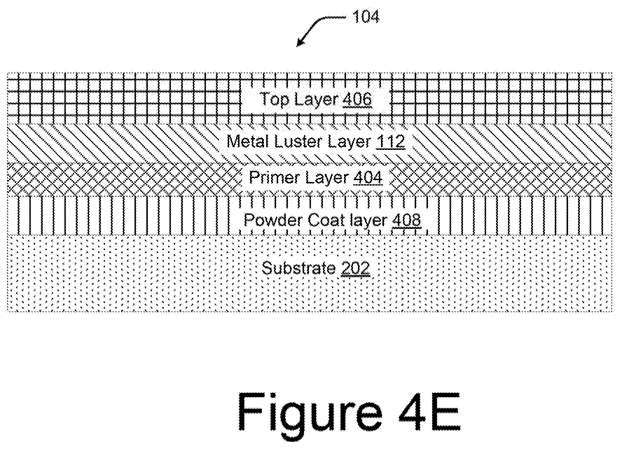

The substrate 202 includes the primary layer 110 and the metal luster layer 112 applied over the primary layer 110. In an example, the primary layer 110 may be a layer disposed directly over a surface. The primary layer 110 may include color pigments, binders, fillers, such as carbon black, carbon nanotubes (CNT), graphene, graphite, titanium dioxide, aluminum oxide, barium sulfate, calcium carbonate, clay, mica, dyes, synthetic pigments, talc, metallic powders, organic powders, color pigments and inorganic powder. The primary layer 110 may be a monolayer or may include multiple layers, such as a base coat layer, a primer layer, and a powder coat layer, as will be explained in detail with respect to FIGS. 4A-4E. In some implementations, the cover 104 may omit the primary layer 110, with the metal luster layer 112 being deposited directly on to the substrate 202.

The primary layer 110 may enhance adhesion of the metal luster layer 112 to the substrate 202. The primary layer 110 may also enhance the aesthetics, for instance, color appearance by way of color pigments. As a result, the metal luster layer 112 may include minimum color pigments to provide better adhesion.

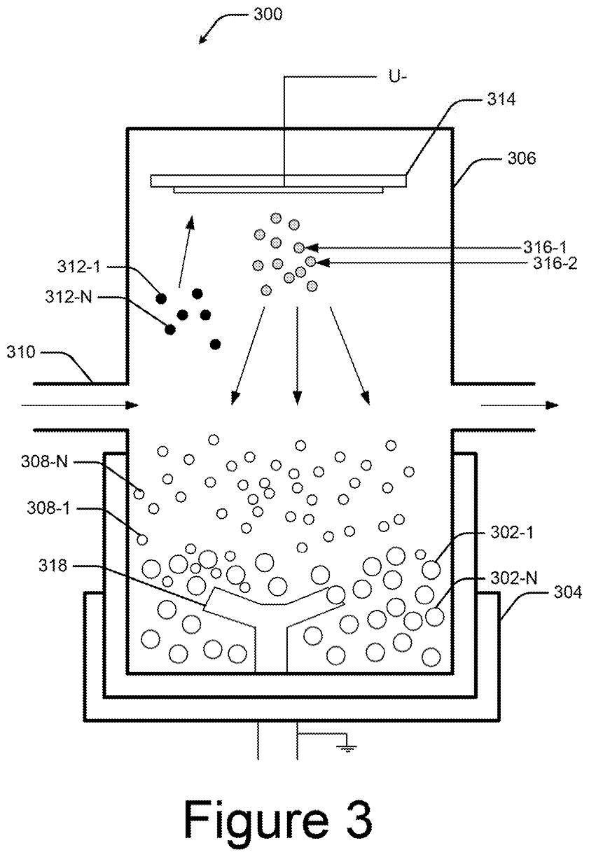

The metal luster layer 112 may be applied using a lustrous paint formulation. To provide luster, the lustrous paint formulation and thus, the metal luster layer 112 may include metal or metallic coated particles, in some implementations. According to an aspect of the present subject matter, base particles, i.e., particles to be coated, may be treated with metal nanoparticles using a PVD process. The base particles are treated such that a non-continuous coating of metal nanoparticles is formed on the surface of the base particles. Thus, the resulting particles are partially coated with the metal nanoparticles. In some implementations, instead of being a part of a paint layer, the base particles may be beads of a powder coat layer. In other implementations, the lustrous paint formulation may include lustrous flakes having a flake substrate coated with a metallic layer and non-continuously suspended in a paint coating. The preparation of lustrous paint formulation is explained in detail with respect to description of FIG. 3. The metal lustrous layer 112 formed using the lustrous paint formulation provides a metal luster owing to the presence of the metal coated particles; however, as the particles may not be completely coated, or the flakes may be non-continuously suspended in the layer, electromagnetic waves transmitted and/or received by the antenna may not be blocked or reflected, thereby not hindering the working of the antenna 102 (shown in FIG. 1).

FIG. 3 a schematic 300 for preparing a lustrous paint formulation, in accordance with an example implementation of the present subject matter. In an example, a physical vapor deposition (PVD) process, such as sputtering deposition and a chemical vapor deposition, may be used. The sputtering deposition may include ion-beam sputtering, reactive sputtering, ion-assisted deposition (IAD), high-target-utilization sputtering, high-power impulse magnetron sputtering (HIPIMS), and gas flow sputtering. Although the preparation has been explained in detail with respect to sputtering deposition, it will be appreciated that other processes may also be used.

In an example, base particles 302-1 . . . 302-N, collectively referred to as base particles 302, may be added in a heat bath 304 of a reaction chamber 306. The base particles 302 may include one of organic particles, inorganic particles, or composite particles. The inorganic particles may include, for instance, ceramic powders, glass beads, glass plates, glass fibers, clays, and hollow inorganic particles. The organic particles include, for instance, plastic beads, polyacrylic, polycarbonate, polyurethane, polyamide, fluoropolymer, polyester, polyphenylene ether, epoxies, hollow organic powders, thermoplastic polymers, or thermoset polymers. As mentioned earlier, the base particles 302 may be coated with metal nanoparticles 308-1 . . . 308-N, collectively referred to as metal nanoparticles 308. The metal nanoparticles 308 may include, for instance, titanium, chromium, nickel, zinc, zirconium, manganese, copper, aluminum, tin, molybdenum, tantalum, tungsten, hafnium, gold, palladium, vanadium, silver, platinum, graphite, graphene, stainless steel and alloy combinations thereof.

In operation, the reaction chamber 306 at one end may be grounded, and at the other end a negative potential may be provided. Further, operating parameters, such as vacuum and temperature of the reaction chamber 306 may be controlled as per PVD processes. In an example, the vacuum may be maintained at about 8×10⁻⁴ Torr to 1×10⁻⁴ Torr and temperature may be maintained at about 120° C.-180° C. Further, the temperature of the heat bath 304 may be maintained at about 120° C.-250° C. Upon setting operating parameters, a sputtering gas may be allowed to enter from an inlet 310 of the reaction chamber 306. The sputtering gas may be an inert gas, such as argon. The sputtering gas provides sputtering ions 312-1 . . . 312-N, such as Ar⁺. The sputtering ions 312-1 . . . 312-N, collectively referred to as sputtering ions 312, upon reaching a sputtering target 314, eject sputtered target atoms 316-1 . . . 316-N, collectively referred to as sputtered target atoms 316. The sputtered target atoms 316 have wide energy distribution, and upon colliding with the metal nanoparticles 308, provide for deposition of the metal nanoparticles 308 over surfaces of the base particles 302. Further, an agitator 318 provided at an end of the reaction chamber 306 having the heat bath 304 provides for uniform deposition of the metal nanoparticles 308 on the base particles 302. The agitator 318 may continuously agitate the reaction mixture to ensure uniform deposition. Also, the agitation may also ensure that particles are partially coated. Further, to ensure partial coating of the PVD processing, time may also be controlled. In an example, upon completion of the surface treatment of the base particles 302, the surface treated base particles may be placed in a holder, such as a plastic holder, and the partially coated base particles may be detected through electromagnetic wave detection.

The above-mentioned process may result in a formulation, referred to as a lustrous paint formulation, having particles with non-continuous metal coating. Using the formulation, a lustrous paint may be prepared to be applied over device covers, such as the cover 104. Owing to the non-continuous metal coating over the base particles 302, transmission of electromagnetic waves by a component, such as the antenna 102 is not blocked as compared to a case where free electrons in a continuous metal layer may have formed a barrier to block the electromagnet waves. Consequently, the antenna functional characteristics, as well as a metallic luster, is preserved and provided.

The above-mentioned process may, in other implementations, result in a lustrous paint formulation where, instead of being applied as a paint layer, may be applied to the cover, or the substrate thereof, or the outer surface thereof, as a powder coat. In other words, the base particles with the non-continuous metal coating may be used as powder beads in a powder coating process to create a lustrous powder coat having non-continuous metal nanoparticles therein. Such a lustrous powder coat may be electrostatically applied to the substrate 202, or the primary layer 110 thereon, and then cured (e.g., by the application of heat) to provide a continuous coat of the lustrous powder coat over the substrate 202, or a desired portion or surface thereof. As described above, the non-continuous metal coating on the base particles of the lustrous powder coat may avoid interfering with the transmission or reception of electromagnetic waves by the antenna, while still providing a metallic, lustrous aesthetic quality to the cover 104.

It should also be noted that, in other implementations, the lustrous paint formulation may be comprised of a lustrous metallic flake paint. The lustrous metallic flake paint may include lustrous flakes comprising a flake substrate coated with a flake coating layer and suspended in a paint coating. The flake coating layer, the flake substrate, or the combination thereof may provide a light reflecting quality to the lustrous flakes. In some implementations, the flake substrate may include one of synthetic mica (e.g., fluorphlogophite), glass platelets (e.g., calcium sodium borosilicate), and aluminum flakes. Further, the flake coating layer may include one of titanium dioxide, iron oxide, silicon dioxide, and tin oxide. For example, synthetic mica flakes may have a flake coating layer of titanium dioxide or iron oxide with a layer thickness of about 10 nanometers (nm)-160 nm. Further, the lustrous flakes may have a glass platelet flake substrate with a flake coating layer of titanium dioxide, silicon dioxide, or tin oxide with a layer thickness of about 10 nm-160 nm. Yet further, the lustrous flakes may have an aluminum flake substrate having a flake coating of silicon dioxide with a layer thickness of about 20 nm-80 nm. The lustrous flakes may generally resist electrical conduction or may be electrically non-conductive. In the case of the flake substrate comprising aluminum flakes, the silicon dioxide may act as an electrical insulator to the aluminum, while still allowing the aluminum to reflect light, thereby giving the flakes a lustrous quality. Additionally, the lustrous flakes may be non-continuous throughout the paint layer, and thus may provide a lustrous finish and/or appearance, yet may avoid interfering with the transmission or reception of electromagnetic waves by the antenna or other communication components.

FIGS. 4A-4E illustrate a cross sectional view of the cover 104, according to various example implementations of the present subject matter. For the sake of brevity, description of FIGS. 4A-4E is provided with reference to the primary layer 110 and the metal luster layer 112. It will be appreciated that multiple other layers, such as heat resistant layers and a chemical resistance layer may also be applied.

Referring to FIG. 4A, a sectional view of the cover 104 of the device 100 is illustrated, in accordance with an example implementation of the present subject matter. On the outer surface 106 of the substrate 202, a base coat layer 402 is applied. The substrate 202 may include a metal, a plastic, a carbon fiber, a ceramic or composites. The base coat layer 402 functions as the primary layer 110 described above. The base coat layer 402 may have a thickness in a range of about 5 μm-20 μm. The base coat layer 402 includes, for instance, at least one of barium sulfate, talc, dyes, and color pigments. In an example, the material forming the base coat layer 402 may be spray coated on the substrate 202 to form the base coat layer 402. In one example, while applying the base coat layer 402, temperature may be maintained in the range of about 60° Celsius (C)-80° C. and may be maintained for 15-40 minutes.

As illustrated, the metal luster layer 112 may be applied over the base coat layer 402 using the lustrous paint formulation. As mentioned above, in some implementations, the base coat layer 402 and/or other layers may be omitted and the metal luster layer 112 may be applied directly on the substrate. The metal luster layer 112 provides metallic luster to substrate 202 in accordance with example processes described above. Additionally, the metal luster layer 112 may provide for additional aesthetic properties; for example, the metal luster layer 112 may include a color coating or a coating to impart certain texture, such as silky and matte, to the cover 104. In an example, the metal luster layer 112 may have a thickness in a range of about 10 micrometers (microns, μm)-25 μm. In one example, while applying the metal luster layer 112, the temperature may be maintained in the range of about 60° C.-80° C. and may kept for about 20-40 minutes.

FIG. 4B illustrates the sectional view of the cover 104 in accordance with another example implementation of the present subject matter. On the outer surface 106 of the substrate 202, a primer layer 404 may be disposed. The primer layer 404 may have a thickness in a range of about 5-15 μm. The primer layer 404 may include fillers, such as carbon black, titanium dioxide, clay, mica, talc, barium sulfate, calcium carbonate, synthetic pigments, metallic powders, aluminum oxide, CNT, graphene, graphite, and organic and inorganic powders.

Over the primer layer 404, the base coat layer 402 may be applied. Thus, the primer layer 404 may be interspersed between the substrate 202 and the base coat layer 402. The primer layer 404 and the base coat layer 402 may collectivley function as the primary layer 110. Further, in case heat resistance properties are to be provided, heat insulating materials may also be added to the primer layer 404 and to the base coat layer 402. Finally, over the base coat layer 402, the metal luster layer 112 may be applied. The base coat layer 402 and the metal luster layer 112 may be provided as described with respect to FIG. 4A.

FIG. 4C illustrates the sectional view of the cover 104, in accordance with another example implementation of the present subject matter. The primer layer 404 is disposed over the outer surface 106 of the substrate 202. The primer layer 404 may function as the primary layer 110. Over the primer layer 404, the metal luster layer 112 may be provided. In said implementations, the metal luster layer 112 may also have properties of the base coat layer 402. An additional layer, a top layer 406, may be disposed as a final layer over the metal luster layer 112, in some implementations. In an example, the top layer may be a clear top layer. In another example, the top layer 406 may be a metal based top layer and include less than 5 wt % aluminum flakes and/or less than 5 wt % of the particles with surface partially coated metal nanoparticles.

Further, FIG. 4D illustrates the sectional view of the cover 104, in accordance with another example implementation of the present subject matter. A powder coat layer 408, which may be a different powder coat layer from the metal luster layer 112 in implementations wherein the metal luster layer 112 comprises a lustrous powder coat, as described above, may be disposed on the outer surface 106 of the substrate 202. The powder coat layer 408 may include fillers, such as carbon black, titanium dioxide, clay, mica, talc, barium sulfate, calcium carbonate, synthetic pigments, metallic powders, aluminum oxide, CNT, graphene, graphite, and organic and inorganic powders.

In an example, the powder adheres to the substrate 202 due to electrostatic charging of the powder. Further, the substrate 202 may include electrically ground material to enhance the charged particle attachment. The powder coat layer 408 normally has higher thickness in order to fill the porous substrate, such as a die-casting magnesium alloy substrate, more effectively in the whole pieces of a magnesium substrate (AZ91). The powder coat layer 408 may have a thickness in a range of about 20-60 μm. The powder coat layer 408 may also provide corrosion resistance at top, side and bottom areas of a die casting magnesium substrate. In one example, for applying the primer coat layer 408 the temperature may be maintained in the range of about 120° C.-190° C. and may kept for about 10-40 minutes.

Over the powder coat layer 408, the primer layer 404 and the base coat layer 402 may be provided, as discussed above. The powder coat layer 408, the primer layer 404, and the base coat layer 402 may together form the primary layer 110. Further, the metal luster layer 112 may be provided in the same manner as described with reference to FIG. 4A.

FIG. 4E illustrates the sectional view of the cover 104, in accordance with yet another example implementation of the present subject matter. The powder coat layer 408 is disposed over the substrate 202. The primer layer 404 may be disposed over the powder coat layer 408, and the metal luster layer 112 may be disposed over the powder coat layer 408. In said example, the metal luster layer 112 may also have properties of the base coat layer 402. Further, the top layer 406 may be provided as the final coat as discussed with respect to FIG. 4C.

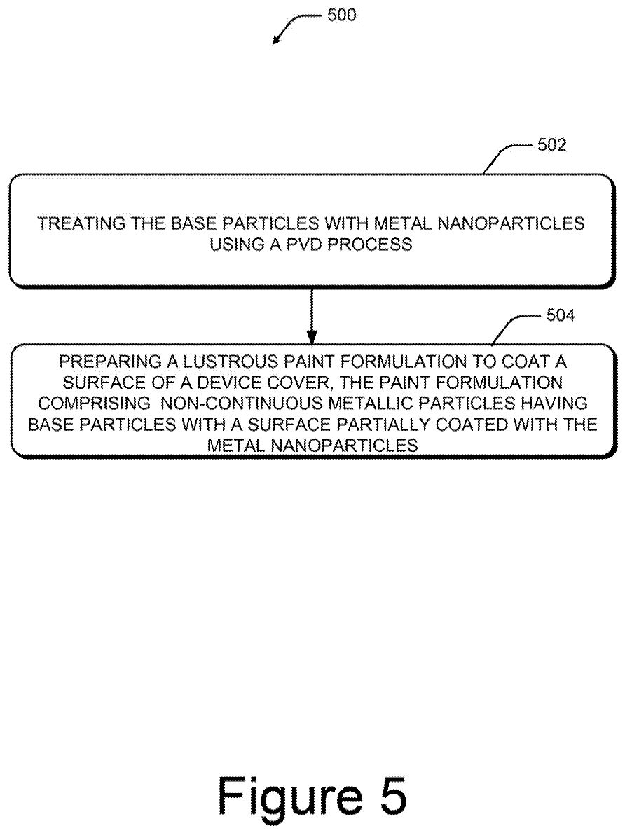

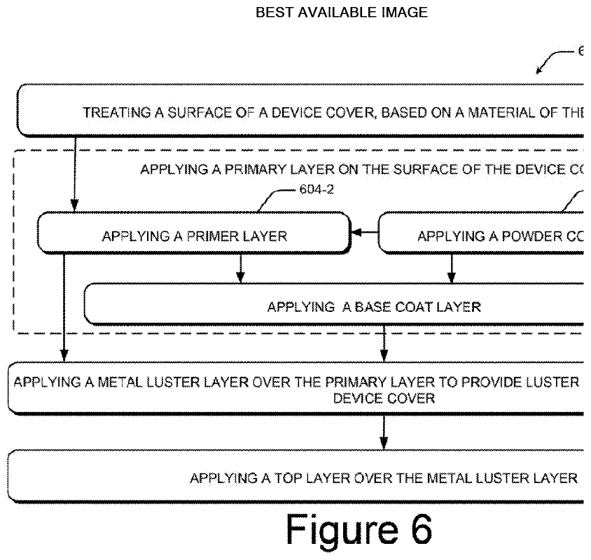

FIG. 5 illustrates a method 500 for preparing a lustrous paint formulation, in accordance with an example implementation of the present subject matter. Further, FIG. 6 illustrates a method 600 for fabricating a device cover, such as the cover 104 for the device 100, in accordance with another example implementation of the present subject matter. The order in which the methods are described is not intended to be construed as a limitation, and any number of the described method blocks can be combined in any appropriate order to execute the methods.

Referring to block 502, base particles may be treated with metal nanoparticles using a physical deposition process. The base particles 302 may include one of organic particles, inorganic particles, or composite particles. The metal nanoparticles 308 may include, for example, titanium, chromium, nickel, zinc, zirconium, manganese, copper, aluminum, tin, molybdenum, tantalum, tungsten, hafnium, gold, palladium, vanadium, silver, platinum, graphite, stainless steel and alloy combinations thereof. In an example, the base particles 302 may be treated with the metal nanoparticles 308 using a sputtering deposition process described in FIG. 3. Further, the reaction mixture may be continuously agitated and/or the process may be time controlled to allow the metal nanoparticles to partially coat a surface of the base particles.

At block 504, a lustrous paint formulation to coat a surface of a device cover may be prepared. For example, upon the surface treatment, partially coated base particles may be selected using electromagnetic detection to form the lustrous paint formulation. Thus, the lustrous paint formulation may be composed of particles partially coated with metal nanoparticles. The lustrous paint formulation, when applied on the surface provide metallic luster to enhance aesthetics.

Referring to FIG. 6, a method for fabricating an article, such as device cover is described, according to an example implementation of the present subject matter. Individual blocks may be deleted from the method 600 without departing from the spirit and scope of the subject matter described herein. At block 602, at least a surface of a device cover is treated prior to applying various coatings. The type of surface treatment which is to be performed is based on a material of a substrate of the cover. For example, in case the substrate comprises a metal, any of polishing, degreasing, activation, and neutralization may be performed in addition to surface cleaning. In another example, in case of a metal substrate, any of die casting, CNC, or forging of the metal substrate may be performed. In another example, a magnesium alloy substrate may be treated using a micro arc oxidation (MAO) process.

At block 604, subsequent surface treatment, a primary layer such as the primary layer 110, is disposed on the treated surface. The primary layer may be provided, for example, for enhancing adhesion to the substrate and enhancing aesthetic appeal, for example, color appearance. In an example, the primary layer may be multilayered comprising various combinations of a powder coat layer, a primer layer, and/or a base coat layer. In another example, the primary layer may be mono-layered or comprise a single layer, such as a base coat layer or a primer layer. The primary layer may be formed in a variety of ways as described below.

In one example, at block 604-1, a powder coat layer, such as the powder coat layer 408 is applied directly to the cover.

At block 604-2, a primer layer, such as the primer layer 404, is applied over the powder layer. In an example, the primer layer and the powder coat layer may together form the primary layer.

In yet another example, at block 604-3, a base coat layer, such as the base coat layer 402 is applied over the primer layer. In said example, the three layers, i.e., the base coat layer, the primer layer, and the powder coat layer, may together form the primary layer.

In another example, the base coat layer may be applied over the powder coat layer. In said example, the base coat layer and the powder coat layer may collectively form the primary layer.

In yet another example, the primary layer may be a mono-layer. In said example, either a base coat layer, as illustrated at block 604-3, may be applied on the cover, or a primer layer, as illustrated at block 604-2, may be applied on the cover.

Upon forming the primary layer, at block 606, a metal luster layer, such as the metal luster layer 112, is applied on the primary layer. The metal luster layer may be applied using a lustrous paint formulation composed of particles, such as the base particles 302 having surfaces partially coated with metal nanoparticles, or lustrous flakes. The metal luster layer 112 provides for luster without interfering with the working of a component, such as the antenna 102, owing to non-continuous coating of metal on the particles.

In yet further implementations, similar methods for coating a device or a cover or substrate thereof may include partially coating organic particles with metal nanoparticles to create powder beads, and preparing a lustrous paint formulation to powder coat a surface of a device cover. The metal nanoparticles may non-continuously coat surfaces of the organic particles. Further, the lustrous paint formulation may include the powder beads with the surfaces non-continuously coated with the metal nanoparticles. In yet further implementations, the method of coating a device or a cover or substrate thereof may further include applying the lustrous paint formulation as part of a metal luster layer over the surface of a device cover, and curing the lustrous paint formulation with the application of heat so that the lustrous paint formulation forms a continuous coating over the surface of the device cover.

What is claimed is:

1. A device cover, comprising:
a substrate; and
a metal luster layer formed using a lustrous paint formulation applied to an outer surface of the substrate, the lustrous paint formulation comprising base particles with surfaces partially coated with metal nanoparticles,
wherein the metal luster layer is applied to the outer surface as a powder coat and the metal nanoparticles are disposed in a non-continuous manner on the base particles.

2. The device cover of claim 1, wherein the metal nanoparticles non-continuously coat the base particles such that the metal luster layer is electrically non-conductive.

3. The device cover of claim 2, wherein the base particles are surface coated with the metal nanoparticles using a physical vapor deposition process.

4. The device cover of claim 2, further comprising a top layer applied over the metal luster layer.

5. The device cover of claim 2, further comprising a primary layer disposed in between the substrate and the metal luster layer.

6. The device cover of claim 5, wherein the primary layer comprises one of a base coat layer and a primer layer.

7. A device, comprising:
an antenna to facilitate communication; and
a device cover housing the antenna, the device cover comprising:
an inner surface facing the antenna;
an outer surface opposite from the inner surface; and
a metal luster layer formed using a lustrous paint formulation applied to the outer surface of the device cover, the lustrous paint formulation including a metallic flake paint with lustrous flakes suspended non-continuously in a paint coating.

8. The device of claim 7, wherein metal luster layer is to not interfere with electromagnetic waves transmitted by the antenna or received by the antenna.

9. The device of claim 8, wherein the lustrous flakes each comprise a flake substrate coated with a flake coating layer.

10. The device of claim 9, wherein the lustrous flakes are electrically non-conductive.

11. The device of claim 9, wherein each flake substrate comprises one of synthetic mica, glass platelets, and aluminum flakes.

12. The device of claim 9, wherein each flake coating layer comprises one of titanium dioxide, iron oxide, silicon dioxide, and tin oxide.

13. A method, comprising:
partially coating organic particles with metal nanoparticles to create powder beads, the metal nanoparticles to non-continuously coat surfaces of the organic particles; and
preparing a lustrous paint formulation to powder coat a surface of a device cover, the lustrous paint formulation comprising the powder beads with the surfaces non-continuously coated with the metal nanoparticles.

14. The method of claim 13, further comprising:
applying the lustrous paint formulation as part of a metal luster layer over the surface of the device cover; and
curing the lustrous paint formulation with the application of heat so that the lustrous paint formulation forms a continuous coating over the surface of the device cover.

15. The method of claim 13, wherein the partially coating comprises:
treating the organic particles in a reaction chamber with metal nanoparticles using a physical vapor deposition process to non-continuously coat the organic particles with metal nanoparticles to the create powder beads.
